(19) United States
(12) Patent Application Publication
(10) Pub. No.: US 2023/0411909 A1
(43) Pub. Date: Dec. 21, 2023

(54) Shielding Arrangement, Shielded Connection and Kit for a Shielding Arrangement

(71) Applicant: TE Connectivity Germany GmbH, Bensheim (DE)

(72) Inventors: Jochen Fertig, Bensheim (DE); Uemit Bulduk, Bensheim (DE)

(73) Assignee: TE Connectivity Germany GmbH, Bensheim (DE)

(21) Appl. No.: 18/333,843

(22) Filed: Jun. 13, 2023

(30) Foreign Application Priority Data
Jun. 14, 2022 (DE) 102022114882.3

(51) Int. Cl. H01R 13/6581; H01R 13/6598; H01R 13/6591

(52) U.S. Cl. CPC H01R 13/6581; H01R 13/6591; H01R 13/6598

(57) ABSTRACT

A shielding arrangement for electrical or electromagnetic shielding includes a first shielding body and a second shielding body connected to the first shielding body to form a shielding volume open at a pair of ends. The first shielding body and the second shielding body are each a different electrically conductive material.

### CROSS-REFERENCE TO RELATED APPLICATION

This application claims the benefit of the filing date under 35 U.S.C. § 119(a)-(d) of German Patent Application No. 102022114882.3, filed on Jun. 14, 2022.

### FIELD OF THE INVENTION

The invention relates to a shielding arrangement for electrical or electromagnetic shielding of a shielding volume and to a kit for a shielding arrangement.

### BACKGROUND

Shielding arrangements are known in the prior art. These are used to protect electrical lines or connections, for example measuring lines or lines for data transmission, from external influences such as electromagnetic stray fields. Materials with high electrical conductivity are often used for shielding. Thus, shielding arrangements for larger shielding volumes are cost-intensive and/or heavy.

### SUMMARY

A shielding arrangement for electrical or electromagnetic shielding includes a first shielding body and a second shielding body connected to the first shielding body to form a shielding volume open at a pair of ends. The first shielding body and the second shielding body are each a different electrically conductive material.

### BRIEF DESCRIPTION OF THE DRAWINGS

Exemplary embodiments of the invention are described by way of the following drawings. In the drawings:

FIG. 1 is a perspective view of a shielding arrangement;

FIG. 2 is a perspective view of the shielding arrangement of FIG. 1 with a housing element;

FIG. 3 is a perspective view of a shielding arrangement according to another embodiment;

FIG. 4 is an exploded perspective view of the shielding arrangement of FIG. 3;

FIG. 5 is an exploded perspective view of a kit according to an embodiment; and

FIG. 6 is a perspective view of a shielded connector according to an embodiment.

### DETAILED DESCRIPTION OF THE EMBODIMENT(S)

In the following, the invention will be described in more detail with reference to the accompanying drawings. The configuration of the shielding arrangement shown in the drawings is purely exemplary and not limiting. Features shown can thus be combined with each other and/or omitted as desired.

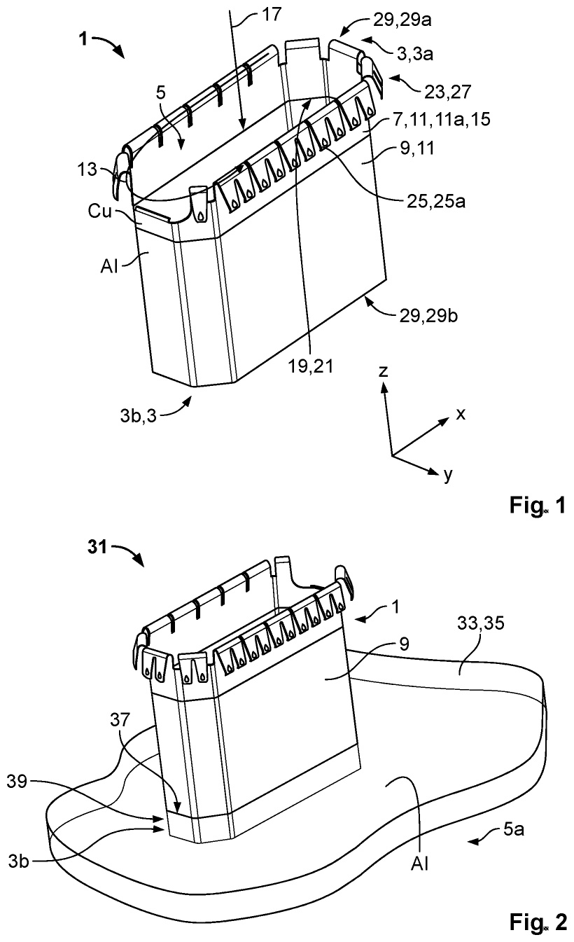

FIG. 1 shows a shielding arrangement 1 that is open at two ends 3 and surrounds a shielding volume 5. The shielding volume 5 is thus determined or defined by an dimension of the shielding arrangement 1 along a height dimension z, as well as a longitudinal dimension x and a transverse dimension y. The shielding arrangement 1 is used for electrical or electromagnetic shielding of the shielding volume 5.

The shielding arrangement 1 comprises a first shielding body 7 and a second shielding body 9, which is connected to the first shielding body 7. Both the first 7 and the second shielding body 9 consist of an electrically conductive material 11, wherein the first shielding body 7 consists of a first electrically conductive material 11a and the second shielding body consists of a second electrically conductive material 11b. The electrically conductive materials 11a and 11b are different. In an embodiment, the first electrically conductive material 11a has particularly good resilient properties in addition to its good electrical conductivity. The different, electrically conductive materials 11a, 11b of the first and second shielding bodies may differ in at least one property from the list comprising density, tensile strength, modulus of elasticity, compressive strength, electrical conductivity, and specific thermal conductivity.

Both shielding bodies 7, 9 are self-contained bodies 15 in a circumferential direction 13. The shielding bodies 7, 9 can, for example, be monolithically self-contained. Alternatively, the shielding bodies 7, 9 may first be formed into a self-contained body 15, such as a ring-shaped body, for example by welding, riveting, caulking or similar methods for connecting two ends. In particular, the ends may be interconnected in the circumferential direction 13. A planar element, such as a metal sheet, is bent along the circumferential direction 13, wherein one end of the planar element facing in the circumferential direction 13 and one end facing against the circumferential direction 13 can be bent toward each other. The free ends may oppose each other in the circumferential direction 13. These ends may be straight (for example, oriented perpendicularly to the circumferential direction 13) or have complementary interlocking joint structures. In other embodiments, the ends of the planar element can also be connected to each other by force-locking or friction-locking. The connecting section, in which the shieling bodies 7, 9 are connected to form the self-contained body 15 can also run at an angle deviating from 90° to the circumferential direction 13.

The first shielding body 7 and/or the second shielding body 9 may be formed as a self-contained band and continuously enclose the shielding volume in a band-like manner. Such self-contained bodies 15 provide a circumferential gapless protection of the shielding volume 5 and elements arranged therein against electromagnetic interference. The shielding volume 5 is thus shielded without gaps.

The first shielding body 7 and the second shielding body 9 are arranged sequentially along a direction of passage 17. The direction of passage 17 is oriented parallel to height dimension z and extends from a first end 3a of the shielding volume 5 to a second end 3b of the shielding volume 5. Along this direction of passage 17, elements that are to be electrically shielded can be passed through or placed in the shielding arrangement 1.

The second shielding body 9 can be larger than the first shielding body 7 in height dimension z or along the direction of passage 17. For example, the second shielding body 9 can be twice as large as the first shielding body 7 in the direction of passage 17.

In an embodiment, the second shielding body 9 is made of an electrically conductive material which shields the shielding volume 5, however it may have a lower electrical conductivity than the material of the first shielding body 7. The material of the second shielding body 9 is thus more cost-effective and further also more lightweight than the material of the first shielding body 7. Thus, both the weight and the manufacturing costs of the shielding arrangement 1 can be reduced.

In an embodiment, the material of the second shielding body 9 may have greater bending or torsional stiffness or hardness than the material of the first shielding body 7. For example, and not limiting, the first shielding body 7 may be made of copper or a copper alloy and the second shielding body 9 may be made of aluminum or an aluminum alloy. Other electrically conductive metals and alloys may also be used in any combination.

Good electrical conductivity is understood to be the typical conductivity of conductors, in particular of metals, which is greater than 10⁶ S/m (10 to the power of 6 Siemens per meter). In an embodiment, the first shielding body 7 consists of copper Cu and the second shielding body 9 of aluminum Al. In other configurations, copper or aluminum alloys may also be used. Both metals, copper Cu and aluminum Al, have a high electrical conductivity (for the pure metals: 58×10⁶ S/m or 37×10⁶ S/m, respectively). For alloys, this value falls below that for the pure metals, however both the pure metals and the alloys are suitable for electrical shielding of the shielding volume 5.

The first shielding body 7 is in electrical contact with the second shielding body 9. This electrical contact can be established by interlocking contours 19 or by an overlap 21. Further possibilities for connection are methods such as joggling or clinching, in which, for example, two metal sheets can be interconnected in a stamping process with the formation of an undercut. Alternatively, the shielding bodies 7, 9 can be riveted together or welded, such as by friction welding, friction stir welding or laser welding. The connection between the first 7 and the second shielding body 9 can thus be form-locking.

Further possibilities for electrically connecting the first shielding body 7 to the second shielding body 9 are material-locking connections, which can be produced by welding, in particular laser welding, friction welding or friction stir welding, for example.

In the configuration shown in FIG. 1, the second shielding body 9 is inserted into the first shielding body 7. Alternatively, the first shielding body 7 can be inserted into the second shielding body 9.

Such a connection provides uninterrupted electrical conductivity between the first and second shielding bodies 7, 9 so that, on one hand, eddy currents generated during shielding can also flow between the first and second shielding bodies 7, 9 and, on the other hand, any heat input introduced into the shielding arrangement 10 by the eddy currents can be dissipated.

The configuration of the shielding arrangement 1 shown in FIG. 1 has a contact arrangement 23 formed on the first shielding body 7. Since the first shielding body 7 is made of copper Cu in an embodiment, which is more elastic than aluminum Al, the contact arrangement 23 may be reversibly deflectable.

The contact arrangement 23 may have at least one contact spring 25, or a plurality of contact springs 25, wherein each of the contact springs 25 extends in different directions away from the first shielding body 7. In the embodiment shown, the contact springs 25 are bent contact springs 25a that form a ring 27, since the contact springs 25 or the bent contact springs 25a are arranged along the circumferential direction 13. For the sake of clarity, only one contact spring or one bent contact spring 25a is provided with a reference sign in FIG. 1. The bent contact springs 25a may, for example, be spring-shaped.

The shielding arrangement 1 is accessible through two oppositely disposed openings 29, a first opening 29a and a second opening 29b.

By using different materials for the first shielding body 7 and the second shielding body 9, both the weight of the shielding arrangement 1 and its manufacturing costs can be reduced without impairing the shielding properties. Since the first shielding body 7 is configured for the electrical contacting of further elements, it has a flexible and reversibly deflectable material such as copper Cu. A more cost-intensive material with good resilient properties can be used in contact areas and a more cost-effective material can be used in areas where only good electrical conductivity is required. Thus, a function of the corresponding areas of the shielding arrangement can determine the material used in these areas.

With regard to its resilience, the second shielding body 9 is subject to lower requirements than the first shielding body 7. The size of the second shielding body 9 can be used to define and scale the size of the shielding volume 5.

Aluminum Al is, on the one hand, a suitable material for electromagnetic shielding and, on the other hand, has the advantage that it is more lightweight and also more cost-effective than copper Cu. Thus, the costs and the weight of the shielding arrangement 1 can be reduced without reducing the electromagnetic shielding of the shielding arrangement 1.

The second shielding body 9 may have stiffening structures, such as ribs.

FIG. 2 shows a shielded connection 31 of the shielding arrangement 1 of FIG. 1 with a housing element 33. The housing element 33 is shown only schematically in the form of a wall 35. The wall 35 of the housing element 33 also represents an electromagnetic shielding, so that the shielding volume 5 surrounded by the shielding arrangement 1 is connected to a further shielding volume 5a, which is formed by the housing element 33 and is enclosed by it.

The wall 35 of the housing element 33 has a receiving opening 37, which is configured to receive the shielding arrangement 1. The size of the receiving opening 37 may be somewhat larger than a base area of the shielding arrangement 1, in particular of the second shielding body 9.

The second shielding body 9 is inserted into the receiving opening 37 at the second end 3b and is electrically and mechanically connected to the wall 35 of the housing element 33 via a material-locked connection 39. Welding methods such as laser welding, friction welding or friction stir welding are suitable for this purpose. In an embodiment, the housing element 33 can also consist of aluminum Al, which facilitates the welding of the second shielding body 9 to the wall 35. The shielding arrangement 1 is thus captively connected to the housing element 33.

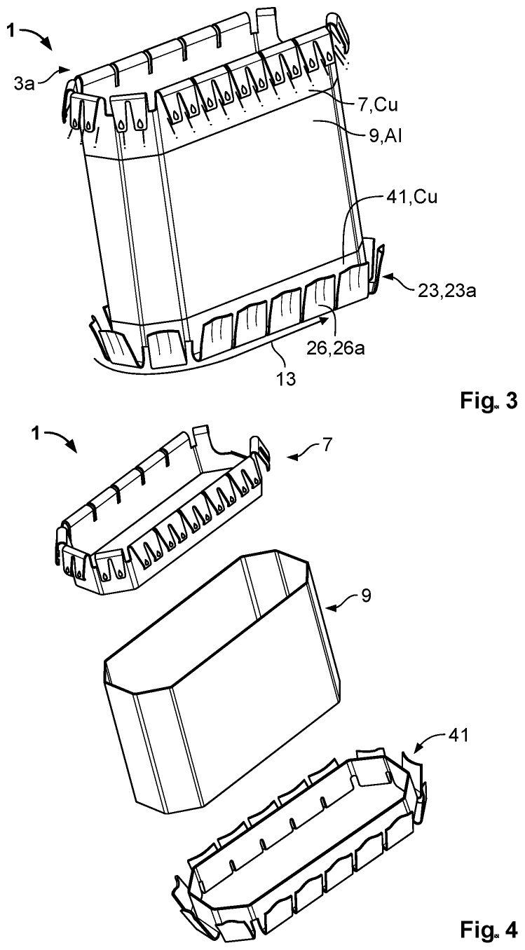

FIG. 3 shows a further configuration of the shielding arrangement 1. Like the shielding arrangement 1 described above, this consists of a first shielding body 7 and a second shielding body 9. Furthermore, the configuration shown has a third shielding body 41, which is arranged opposite the first shielding body 7 at the second end 3b of the shielding arrangement 1. The second shielding body 9 is arranged between the first shielding body 7 and the third shielding body 41 and, in an embodiment, the third shielding body 41 is connected to the first shielding body 7 and the second shielding body 9.

The third shielding body 41 is connected to the second shielding body 9. A connection between the third shielding body 41 and the second shielding body 9 may be identical to the connection between the first shielding body 7 and the second shielding body 9. Alternatively, for the connection between the second 9 and third shielding body 41, other methods or elements can be used than for the connection between the first 7 and second shielding body 9. The possible ways of connecting two shielding bodies 7, 9 is described above and can be transferred to the connection of the shielding bodies 9, 41.

The third shielding body 41 has a further contact arrangement 23a, as shown in FIG. 3. The further contact arrangement 23a also comprises a plurality of further contact springs 26, which are also arranged along the circumferential direction 13, however, at the second end 3b and not at the first end 3a, and extend away from the third shielding body 41. The further contact springs 26 are further bent contact springs 26a.

The third shielding body 41 can be made of the same material as the first shielding body 7. The third shielding body 41 can also be configured with further elements, for example an aggregate housing, for electrical and/or mechanical connection.

By the contact arrangement 23 or the further contact arrangement 23a, the shielding arrangement 1 can be electrically and/or mechanically connected to further elements. In an embodiment, the first and/or third shielding body 7, 41 is made of a material with high resilience and high electrical conductivity, for example with higher resilience and/or higher electrical conductivity than the material of the second shielding body 9.

In the configuration of the shielding arrangement 1 shown in FIG. 3, the bent contact springs 25a as well as the further bent contact springs 26a face away from the respective end 3a or 3b in the direction of the second shielding body 9.

The contact arrangement 23 and/or the further contact arrangement 23a may comprise at least two bent contact springs 25a and/or at least two further bent contact springs 26a, which may further extend in different directions. In other configurations, three, four, five or more bent contact springs 25a or further bent contact springs 26a may be provided, which may be arranged along the circumference of the first and or third shielding body 7, 41, for example equidistantly.

The plurality of contact springs 25 and/or the further contact springs 26 can ensure reliable electrical contact between the first shielding body 7 and a further element and/or vibration damping of the shielding arrangement 1. All contact springs 25, 26 can face in different directions, for example perpendicularly away from the circumference of the first shielding body 7.

The configuration of the shielding arrangement 1 shown in FIG. 3 can also form a shielded connection 31 with a housing element 33. For this purpose, the shielding arrangement 1 can be inserted into the receiving opening 37 (see FIG. 2) such that the further bent contact springs 26a are deflected towards the second shielding body 9 when inserted into the receiving opening 37 and abut against an inner wall of the receiving opening 37. In this case, the further bent contact springs 26a exert a contact pressure on the inner wall of the receiving opening 37, which on the one hand holds the shielding arrangement 1 securely in the receiving opening 37 and on the other hand vibrations of the housing element 33 are damped by the further bent contact springs 26a and are not transmitted directly to the shielding arrangement 1.

The at least two bent contact springs 25a and/or the at least two further bent contact springs 26a may each be bent in the direction of the second shielding body 9 and/or extend in the direction of the second shielding body 9.

In an embodiment, the third shielding body 41 is made of copper Cu, just like the first shielding body 7.

The second shielding body 9 proportionally requires the most material, and is made of a cheaper and/or more lightweight material than the first and second shielding bodies 7, 9. Since the second shielding body 9 is not used for electrical and/or mechanical contacting of another shielding arrangement or aggregate, the requirements on the resilience of the second shielding body 9 are lower than those on the resilience of the first and/or third shielding body 7, 41. This has the advantage that the entire shielding arrangement 10 can have a lower weight and can also be manufactured more cost-effectively.

By connecting the second shielding body 9 to the first shielding body 7 and the third shielding body 41, heat input induced by electromagnetic radiation into the shielding arrangement 1 can be effectively dissipated. Furthermore, the connection of the shielding bodies 7, 9, 41 to each other allows electrically possible paths of the eddy currents induced by the electromagnetic radiation to be not locally limited and thus the shielding arrangement 1 is not locally heated.

In FIG. 4, the shielding arrangement 1 of FIG. 3 is shown in an exploded view, wherein in this configuration the second shielding body 9 can be inserted into the first shielding body 7 as well as into the third shielding body. In other configurations, the first shielding body 7 and/or the third shielding body 41 may be insertable into the second shielding body 9. The shielding bodies 7, 9, 41 can also have interlocking structures. These interlocking structures can, for example, be in the form of a pocket when viewed in the circumferential direction 13.

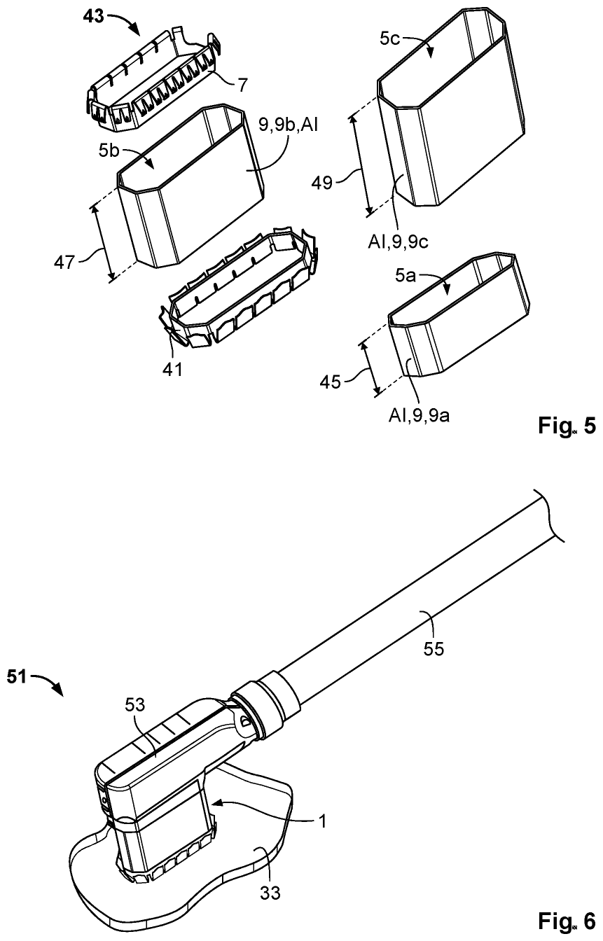

FIG. 5 shows a kit 43 for a shielding arrangement 1. This kit 43 includes the first shielding body 7 and a plurality of second shielding bodies 9. Optionally, the kit 43 may also include the third shielding body 41, as shown in FIG. 5. In the example shown, the kit 43 includes three second shielding bodies 9, which are referred to as shielding bodies 9a, 9b and 9c to distinguish them. The second shielding bodies 9a, 9b and 9c are all made of aluminum Al, but can also consist of different materials.

The second shielding bodies 9a, 9b and 9c have different lengths 45, 47, 49 along the direction of passage 17 so that the kit 43 can be used to create or define shielding volumes 5 of different sizes. In this case, a first shielding volume 5a is smaller than a second shielding volume and the second shielding volume 5b is smaller than a third shielding volume 5c. The kit 43 is thus versatilely applicable to cover different application areas or cases with different shielding volumes 5. In a further embodiment, the kit 43 may further comprise a third shielding body 41 of any of the configurations described above.

By the first (in the second described embodiment also the third) shielding body 7, 41 an electrical and/or mechanical connection to a further element can always be established and at the same time, by selecting a suitable second shielding body 9, the size of the shielding volume 5 can be adapted to the respective application. Thus, the kit 43 can be used universally for shielding volumes 5 of different sizes. For this purpose, only the suitable second shielding body 9 has to be selected and connected to the first (or the first and the third) shielding body 7, 41.

FIG. 6 shows a shielded connector 51 having a connector housing 53 which at least partially encloses a shielding volume 5, and a configuration of a shielding arrangement 1 described above. The shielded connector 51 is inserted into a housing element 33 and connected to a shielded cable 55.

In a further configuration, the shielded connector 51 may have a further shielding arrangement on a cable side facing away from a mating face of the connector. The further shielding arrangement can be electrically and/or mechanically connected to the shielding arrangement 1 according to the invention. This additional shielding arrangement can be connected to the shielding arrangement 1 according to the invention in a materially locked manner. The further shielding arrangement can, for example, be a shielding of a cable. The further shielding arrangement can also shield a volume and can differ from the shielding arrangement 1 of the shielded connector 51. The shielding arrangement 1 and the further shielding arrangement can also be configured in the same way.

Continuous shielding can also be ensured on the connector side, i.e. that side of the connector 51 to which the mating face faces. Thus, a shielded connection can be provided between a housing element 33 and a shielding arrangement 1 described above. In such a shielded connection, the housing element 33 can have a receiving opening in which the shielding arrangement 1 can be received and in which the shielding arrangement 1 can be mechanically and electrically connected to the housing element 33 by spring elements or by a material bond.

The shielding arrangement 1 can comprise the first and second shielding bodies 7, 9, wherein the second shielding body 9 can be inserted or fitted into the receiving opening of the housing element 33 and can be connected to the housing element 33. This connection can be made by welding, for example.

In another exemplary configuration, the shielding arrangement 1 may comprise the first, the second and the third shielding bodies 7, 9, 41, wherein the third shielding body 41 can be inserted or fitted into the receiving opening of the housing element 33 and can be connected to the housing element 33 via contact springs. This connection can be made, for example, by a latching mechanism and, in particular, can be repeatedly released. The contact springs 25 contact the housing element 33 in a resilient manner, so that a continuous vibration-damped connection can be made or is made between the shielding arrangement 1 and the housing element 33.

What is claimed is:

1. A shielding arrangement for electrical or electromagnetic shielding, comprising:
a first shielding body; and
a second shielding body connected to the first shielding body to form a shielding volume open at a pair of ends, the first shielding body and the second shielding body are each a different electrically conductive material.

2. The shielding arrangement of claim 1, wherein the first shielding body and/or the second shielding body is a self-contained body in a circumferential direction.

3. The shielding arrangement of claim 2, wherein the self-contained body is formed by connecting a pair of free ends of the first shielding body and/or the second shielding body.

4. The shielding arrangement of claim 3, wherein the pair of free ends of the first shielding body and/or the second shielding body are connected by at least one of interlocking joint structures, welding, riveting, and caulking.

5. The shielding arrangement of claim 1, wherein the first shielding body and the second shielding body are arranged sequentially along a direction of passage facing from a first open end of the shielding volume to a second open end of the shielding volume.

6. The shielding arrangement of claim 5, wherein the second shielding body has a larger dimension in the direction of passage than the first shielding body.

7. The shielding arrangement of claim 1, wherein the first shielding body and the second shielding body have interlocking or overlapping contours.

8. The shielding arrangement of claim 1, wherein the first shielding body and the second shielding body are connected to one another in at least one of a form-locking manner, a material-locking manner, and a force-locking manner.

9. The shielding arrangement of claim 1, further comprising a third shielding body, the second shielding body is arranged between and connected to the first shielding body and the third shielding body.

10. The shielding arrangement of claim 9, wherein the first shielding body and/or the third shielding body has a contact arrangement.

11. The shielding arrangement of claim 10, wherein the contact arrangement and/or a further contact arrangement of the third shielding body has a ring of bent contact springs.

12. The shielding arrangement of claim 11, wherein the ring of bent contact springs is bent toward the second shielding body.

13. The shielding arrangement of claim 9, wherein the first shielding body, the second shielding body, and the third shielding body are arranged sequentially along a direction of passage facing from a first open end of the shielding volume to a second open end of the shielding volume.

14. The shielding arrangement of claim 13, wherein the second shielding body has a larger dimension in the direction of passage than the first shielding body and/or the third shielding body.

15. A shielded connector, comprising:
a connector housing;
a shielding volume at least partially enclosed by the connector housing; and
a shielding arrangement enclosing and electrically shielding the shielding volume, the shielding arrangement includes a first shielding body and a second shielding body connected to the first shielding body, the first shielding body and the second shielding body are each a different electrically conductive material.

16. A shielded connection, comprising:
a housing element having a receiving opening; and
a shielding arrangement arranged in the receiving opening, the shielding arrangement includes a first shielding body and a second shielding body connected to the first shielding body, the first shielding body and the second shielding body are each a different electrically conductive material, the shielding arrangement is mechanically and electrically connected to the housing element by a plurality of contact springs or by a material bond.

17. A kit for a shielding arrangement, comprising:
a first shielding body; and
a plurality of second shielding bodies each having a different length in a direction of passage, each of the second shielding bodies is interchangeably connectable to the first shielding body.
